(19) United States
(12) Patent Application Publication
(10) Pub. No.: US 2023/0104202 A1
(43) Pub. Date: Apr. 6, 2023

(54) POWER RECEPTION DEVICE AND METHOD FOR CONTROLLING CHARGING OF POWER RECEPTION DEVICE

(71) Applicant: Samsung Electronics Co., Ltd., Suwon-si (KR)

(72) Inventors: Changhak O, Suwon-si (KR); Kyungmin PARK, Suwon-si (KR); Mingi SONG, Suwon-si (KR)

(21) Appl. No.: 17/854,754

(22) Filed: Jun. 30, 2022

Related U.S. Application Data
(63) Continuation of application No. PCT/KR2022/009329, filed on Jun. 29, 2022.

(30) Foreign Application Priority Data
Sep. 28, 2021 (KR) 10-2021-0128291

(51) Int. Cl. H02J 50/12; H02J 7/00; H02J 50/80; G01R 19/10

(52) U.S. Cl. CPC H02J 50/12; H02J 7/0047; H02J 7/00712; H02J 50/80; G01R 19/10

(57) ABSTRACT

A power reception device is provided. The power reception device includes a power reception circuity, a communication circuit, a modulation depth monitoring circuit, and a processor electrically connected with the power reception circuity, the communication circuit, and the modulation depth monitoring circuit. The power reception circuity includes a receive circuit that receives power from a wireless power transmitter and includes a coil and a first capacitor and a rectifier circuit that rectifies the power received by the receive circuit to convert the power into dual connectivity (DC) power. The communication circuit includes a plurality of detuning switching circuitries, each of which includes a second capacitor and a switch and changes a voltage of the power received in the coil and a modulation circuit that turns on or off the switch based on a control signal received from the processor. The modulation depth monitoring circuit monitors a voltage of the rectified DC power to measure a modulation depth and provides the processor with the modulation depth. The processor identifies a detuning switching circuity to perform data modulation among the plurality of detuning switching circuitries based on the modulation depth, controls the modulation circuit such that data is modulated by means of the identified detuning switching circuity and limits the modulation depth such that the modulation depth belongs to a specified range, and controls the modulation circuit based on the data to be transmitted to the wireless power transmitter.

### CROSS-REFERENCE TO RELATED APPLICATION(S)

This application is a continuation application, claiming priority under § 365(c), of an International application No. PCT/KR2022/009329, filed on Jun. 29, 2022, which is based on and claims the benefit of a Korean patent application number 10-2021-0128291, filed on Sep. 28, 2021, in the Korean Intellectual Property Office, the disclosure of which is incorporated by reference herein in its entirety.

### TECHNICAL FIELD

The disclosure relates to a power reception device and a method for controlling charging of the power reception device.

### BACKGROUND ART

An electronic device may be connected with a charging device to be charged. In the disclosure, the electronic device may be collectively referred to as a power reception device. In the disclosure, the charging device may be collectively referred to as a power transmission device. The power transmission device may wirelessly transmit power to the power reception device. The power reception device may receive power from the power transmission device. The power reception device and the power transmission device may make up a wireless charging system set to an international standard in the wireless power consortium (WPC).

The power reception device and the power transmission device included in the wireless charging system set to the international standard in the WPC may perform inband communication to wirelessly transmit and receive power. The power reception device may vary a capacitance value of a capacitor disposed in a previous stage of a rectifier when performing the inband communication. The power reception device may vary the capacitance value of the capacitor disposed in the previous stage of the rectifier to modulate a signal for the inband communication.

The above information is presented as background information only to assist with an understanding of the disclosure. No determination has been made, and no assertion is made, as to whether any of the above might be applicable as prior art with regard to the disclosure.

### DISCLOSURE

### Technical Problem

A power reception device may close or open a switch connected with a capacitor to vary a capacitance value of the capacitor disposed in a previous stage of a rectifier when performing inband communication. When closing the switch connected with the capacitor, modulation of the signal may be enabled. When opening the switch connected with the capacitor, the modulation of the signal may be disabled.

The capacitance value of the capacitor disposed in the previous stage of the rectifier may be preset. When closing or opening the switch connected with the capacitor, a rectified voltage of an electronic device may be changed. When the modulation of the signal is enabled and when the modulation of the signal is disabled, the rectified voltage of the electronic device may be changed.

A difference value between a magnitude of the rectified voltage of the electronic device when the modulation of the signal is enabled and a magnitude of the rectified voltage of the electronic device when the modulation of the signal is disabled may be collectively referred to as a modulation depth. When the modulation depth increases, audible noise may occur when modulating the signal.

Aspects the disclosure are to address at least the above-mentioned problems and/or disadvantages and to provide at least the advantages described below. Accordingly, an aspect of the disclosure is to provide a method for reducing audible noise generated when modulating a signal while wirelessly charging a power reception device and an electronic device to be applied to the method.

Additional aspects will be set forth in part in the description which follows and, in part, will be apparent from the description, or may be learned by practice of the presented embodiments.

### Technical Solution

In accordance with an aspect of the disclosure, a power reception device is provided. The power reception device includes a power reception circuity, a communication circuit, a modulation depth monitoring circuit, and at least one processor electrically connected with the power reception circuity, the communication circuit, and the modulation depth monitoring circuit. The power reception circuity includes a receive circuit configured to receive power from a wireless power transmitter and include a coil and a first capacitor and a rectifier circuit configured to rectify the power received by the receive circuit to convert the power into dual connectivity (DC) power. The communication circuit includes a plurality of detuning switching circuitries, each of which includes a second capacitor and a switch and changes a voltage of the power received in the coil and a modulation circuit configured to turn on or off the switch based on a control signal received from the at least one processor. The modulation depth monitoring circuit may monitor a voltage of the rectified DC power to measure a modulation depth and may provide the at least one processor with the modulation depth. The at least one processor may identify a detuning switching circuity to perform data modulation among the plurality of detuning switching circuitries based on the modulation depth, may control the modulation circuit such that data is modulated by means of the identified detuning switching circuity and may limit the modulation depth such that the modulation depth belongs to a specified range, and may control the modulation circuit based on the data to be transmitted to the wireless power transmitter.

In accordance with another aspect of the disclosure, a method for controlling charging of a power reception device is provided. The method includes receiving power from a wireless power transmitter, rectifying the received power to convert the received power into DC power, monitoring a voltage of the rectified DC power to measure a modulation depth, identifying a detuning switching circuity to perform data modulation based on the modulation depth, controlling a modulation circuit such that data is modulated by means of the identified detuning switching circuity and limiting the modulation depth such that the modulation depth belongs to a specified range, and controlling the modulation circuit based on the data to be transmitted to the wireless power transmitter.

### Advantageous Effects

According to various embodiments disclosed in the disclosure, the power reception device may limit a modulation depth to within a specified range when modulating a signal for inband communication. Thus, audible noise generated when modulating the signal may be reduced.

Furthermore, according to various embodiments disclosed in the disclosure, as the maximum threshold value of a specified range limiting the modulation depth may be set to be low, audible noise may be reduced.

In addition, various effects ascertained directly or indirectly through the disclosure may be provided.

Other aspects, advantages, and salient features of the disclosure will become apparent to those skilled in the art from the following detailed description, which, taken in conjunction with the annexed drawings, discloses various embodiments of the disclosure.

### DESCRIPTION OF DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a block diagram illustrating the power management module and the battery according to an embodiment of the disclosure;

FIG. 3 is a block diagram illustrating a system including a power transmission device and a power reception device according to an embodiment of the disclosure;

FIG. 4 is a drawing illustrating inband communication of a wireless charging system set to an international standard in the WPC according to an embodiment of the disclosure;

FIG. 5 is a drawing illustrating a wireless charging system set to an international standard in the WPC according to an embodiment of the disclosure;

FIG. 6A is a block diagram illustrating a power reception device according to an embodiment of the disclosure;

FIG. 6B is a block diagram illustrating a power reception device according to an embodiment of the disclosure;

FIG. 6C a flowchart illustrating a method for controlling charging of a power reception device according to an embodiment of the disclosure;

FIG. 7 is a table illustrating a modulation control table according to an embodiment of the disclosure;

FIG. 8 is a graph illustrating calculating an average value of the modulation depth according to an embodiment of the disclosure;

FIG. 9 is a graph illustrating calculating an average value of the modulation depth according to an embodiment of the disclosure;

FIG. 10A is a graph illustrating a change in modulation voltage when controlling a modulation depth according to an embodiment of the disclosure;

FIG. 10B is a graph illustrating a change in modulation voltage when controlling a modulation depth according to an embodiment of the disclosure;

FIG. 10C is a graph illustrating a change in modulation voltage when controlling a modulation depth according to an embodiment of the disclosure;

FIG. 10D is a graph illustrating a change in modulation voltage when controlling a modulation depth according to an embodiment of the disclosure;

FIG. 11A is a flowchart illustrating a method for controlling a modulation depth to control a modulation voltage according to an embodiment of the disclosure;

FIG. 11B is a flowchart illustrating a method for controlling a modulation depth to control a modulation voltage according to an embodiment of the disclosure;

FIG. 11C is a flowchart illustrating a method for controlling a modulation depth to control a modulation voltage according to an embodiment of the disclosure;

FIG. 11D is a flowchart illustrating a method for controlling a modulation depth to control a modulation voltage according to an embodiment of the disclosure; and

FIG. 12 is a flowchart illustrating a method for controlling a modulation depth according to an embodiment of the disclosure.

Throughout the drawings, it should be noted that like reference numbers are used to depict for the same or similar elements, features, and structures.

### MODE FOR INVENTION

The following description with reference to accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and equivalents.

It is to be understood that the singular forms “a,” “an,” and “the” include plural referents unless the context clearly dictates otherwise. Thus, for example, reference to “a component surface” includes reference to one or more of such surfaces.

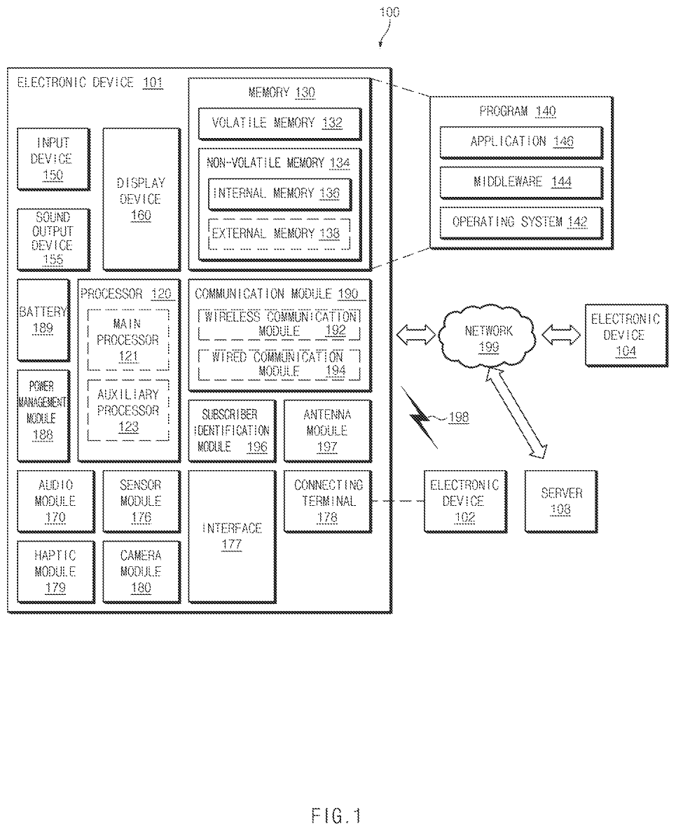

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power Iine communication (PLC) module). A corresponding one of these communication modules may communicate with the external electronic device via the first network 198 (e.g., a short-range communication network, such as Bluetooth™ wireless-fidelity (Wi-Fi) direct, or infrared data association (IrDA)) or the second network 199 (e.g., a long-range communication network, such as a legacy cellular network, a 5th generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4th generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

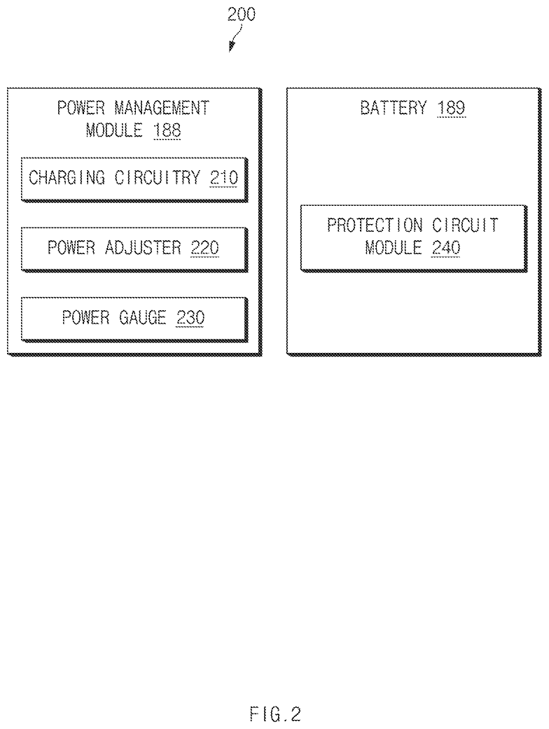

FIG. 2 is a block diagram 200 illustrating the power management module 188 and the battery 189 according to an embodiment of the disclosure.

Referring to FIG. 2, the power management module 188 may include charging circuitry 210, a power adjuster 220, or a power gauge 230. The charging circuitry 210 may charge the battery 189 by using power supplied from an external power source outside the electronic device 101. According to an embodiment, the charging circuitry 210 may select a charging scheme (e.g., normal charging or quick charging) based at least in part on a type of the external power source (e.g., a power outlet, a USB, or wireless charging), magnitude of power suppliable from the external power source (e.g., about 20 Watt or more), or an attribute of the battery 189, and may charge the battery 189 using the selected charging scheme. The external power source may be connected with the electronic device 101, for example, directly via the connecting terminal 178 or wirelessly via the antenna module 197.

According to an embodiment, the power adjuster 220 may generate a plurality of powers having different voltage levels or different current levels by adjusting a voltage level or a current level of the power supplied from the external power source or the battery 189. According to another embodiment, the power adjuster 220 may adjust the voltage level or the current level of the power supplied from the external power source or the battery 189 into a different voltage level or current level appropriate for each of some of the components included in the electronic device 101. According to yet another embodiment, the power adjuster 220 may be implemented in the form of a low drop out (LDO) regulator or a switching regulator. The power gauge 230 may measure use state information about the battery 189 (e.g., a capacity, a number of times of charging or discharging, a voltage, or a temperature of the battery 189).

According to an embodiment, the power management module 188 may determine, using, for example, the charging circuitry 210, the power adjuster 220, or the power gauge 230, charging state information (e.g., lifetime, over voltage, low voltage, over current, over charge, over discharge, overheat, short, or swelling) related to the charging of the battery 189 based at least in part on the measured use state information about the battery 189. According to another embodiment, the power management module 188 may determine whether the state of the battery 189 is normal or abnormal based at least in part on the determined charging state information. If the state of the battery 189 is determined to abnormal, the power management module 188 may adjust the charging of the battery 189 (e.g., reduce the charging current or voltage, or stop the charging). According to yet another embodiment, at least some of the functions of the power management module 188 may be performed by an external control device (e.g., the processor 120).

The battery 189, according to an embodiment, may include a protection circuit module (PCM) 240. The PCM 240 may perform one or more of various functions (e.g., a pre-cutoff function) to prevent a performance deterioration of, or a damage to, the battery 189. The PCM 240, additionally or alternatively, may be configured as at least part of a battery management system (BMS) capable of performing various functions including cell balancing, measurement of battery capacity, count of a number of charging or discharging, measurement of temperature, or measurement of voltage.

According to an embodiment, at least part of the charging state information or use state information regarding the battery 189 may be measured using a corresponding sensor (e.g., a temperature sensor) of the sensor module 176, the power gauge 230, or the power management module 188. According to another embodiment, the corresponding sensor (e.g., a temperature sensor) of the sensor module 176 may be included as part of the PCM 240, or may be disposed near the battery 189 as a separate device.

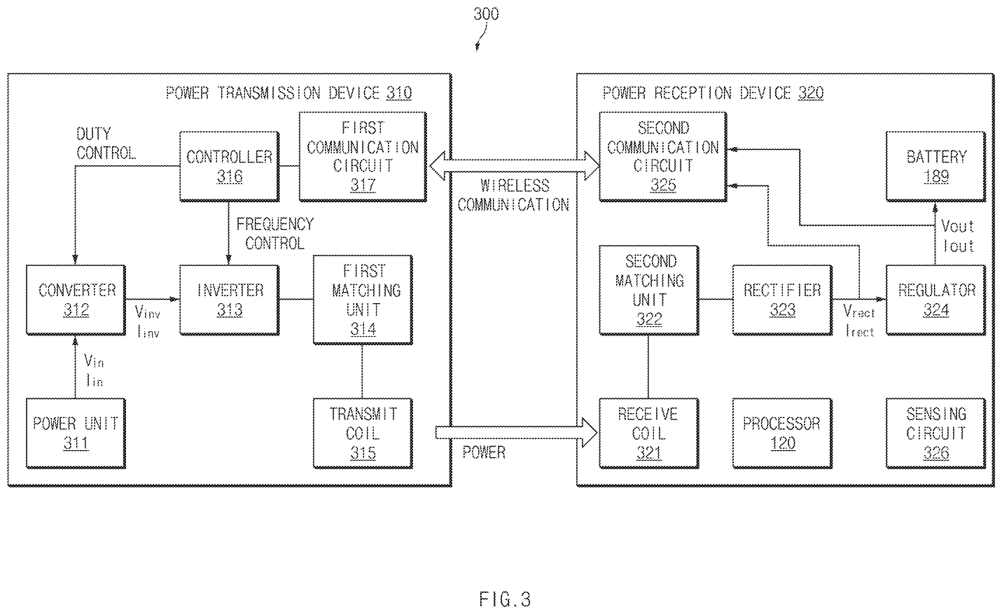

FIG. 3 is a block diagram illustrating a system 300 including a power transmission device 310 and a power reception device 320 according to an embodiment of the disclosure. The case where power is transmitted in an induction scheme is exemplified in FIG. 3. However, it is not limited thereto. The system 300 according to the disclosure is applicable to when power is transmitted in a resonant scheme.

In an embodiment, the power transmission device 310 may be a power supply device or a charging device. The power reception device 320 may be an electronic device (e.g., an electronic device 101 of FIG. 1). For example, the power reception device 320 may be a portable electronic device or a wearable electronic device. The power transmission device 310 may wirelessly transfer power to the power reception device 320. The power reception device 320 may be wirelessly charged by the power transmission device 310. In an embodiment, the power transmission device 310 may be a portable electronic device or a wearable electronic device similar to the power reception device 320.

In another embodiment, the power transmission device 310 may include a power unit 311, a converter 312, an inverter 313, a first matching unit 314, a transmit coil 315, a controller 316, and a first communication circuit 317.

In yet another embodiment, the power unit 311 may receive power from the outside. The power unit 311 may transfer an input voltage Vin and an input current Iin to the converter 312.

In an embodiment, the converter 312 may receive the input voltage Vin and the input current Iin from the power unit 311. The converter 312 may generate an inverter voltage Vinv and an inverter current Iinv based on the input voltage Vin and the input current Iin. The converter 312 may transfer the inverter voltage Vinv and the inverter current Iinv to the inverter 313. The converter 312 may be a DC-DC converter.

In another embodiment, the inverter 313 may receive the inverter voltage Vinv and the inverter current Iinv from the converter 312. The inverter 313 may invert and transfer the inverter voltage Vinv and the inverter current Iinv to the first matching unit 314. The inverter 313 may further a power amplifier (PA) or may be replaced with the PA.

In yet another embodiment, the first matching unit 314 may receive the inverter voltage Vinv and the inverter current Iinv from the inverter 313. The inverter voltage Vinv and the inverter current Iinv converted into AC may be output from the inverter 313. The first matching unit 314 may transfer the inverter voltage Vinv and the inverter current Iinv converted into AC to the transmit coil 315. The first matching unit 314 may compensate for or adjust an input impedance of a transmission end of the transmit coil 315. The first matching unit 314 may be an impedance matching network

In an embodiment, the transmit coil 315 may receive the inverter voltage Vinv and the inverter current Iinv, which are inverted, from the first matching unit 314. The transmit coil 315 may wirelessly transmit power based on the inverter voltage Vinv and the inverter current Iinv, which are inverted.

In another embodiment, the controller 316 may control a duty of the converter 312. The duty may refer to the ratio of turned-on time lengths in a switching operation of controlling turn-on and turn-off of the converter 312 during a specified time interval. The duty may be changed to control a ratio of a magnitude of the inverter voltage Vinv or a magnitude of the inverter voltage Vinv compared with the input voltage Vin. The duty may be referred to as a duty cycle or a duty ratio. The controller 316 may control a frequency of the inverter 313. The frequency of the inverter 313 may be an operating frequency of the power transmission device 310. The operating frequency may be changed to change an input impedance of the system 300. Thus, the operating frequency may be changed to control an inverter current Iinv output from the inverter 313 and an inverter power Pinv output from the inverter 313. The controller 316 may be a microprocessor.

In yet another embodiment, the first communication circuit 317 may perform wireless communication with a second communication circuit 325 of the power reception device 320. The first communication circuit 317 may receive information associated with a state of charge of the power reception device 320. The first communication circuit 317 may receive information associated with a voltage, a current, and/or a power of the power reception device 320. The first communication circuit 317 may deliver the information associated with the voltage, the current, and/or the power of the power reception device 320 to the controller 316.

In an embodiment, the power reception device 320 may include a processor 120, a receive coil 321, a second matching unit 322, a rectifier 323, a regulator 324, a battery 189, a second communication circuit 325 (e.g., a wireless communication module 192 of FIG. 1), and a sensing circuit 326.

In another embodiment, the receive coil 321 may receive the power wirelessly transmitted from the transmit coil 315. The receive coil 321 may transfer the received power to the second matching unit 322.

In yet another embodiment, the second matching unit 322 may receive the power from the receive coil 321. The second matching unit 322 may transfer the power to the rectifier 323. The second matching unit 322 may adjust or compensate for input impedance shown from the receive coil 321 of the power reception device 320 to a load end (e.g., the battery 189). The second matching unit 322 may be an impedance matching network.

In an embodiment, the rectifier 323 may receive the power from the second matching unit 322. The rectifier 323 may generate a rectified voltage Vrect and a rectified current Irect based on the received power. The rectifier 323 may transfer the rectified voltage Vrect and the rectified current Irect to the regulator 324.

In another embodiment, the regulator 324 may receive the rectified voltage Vrect and the rectified current Irect from the rectifier 323. The regulator 324 may generate an output voltage Vout and an output current Tout based on the received rectified voltage Vrect and the received rectified current Irect. The regulator 324 may transfer the output voltage Vout and the output current Tout to the battery 189 to charge the battery 189. The battery 189 may act as a load.

In yet another embodiment, the second communication circuit 325 may receive data about the rectified voltage Vrect, the rectified current Irect, the output voltage Vout, and the output current Tout. The second communication circuit 325 may perform wireless communication with the power transmission device 310.

In an embodiment, the wireless communication performed by the power reception device 320 and the power transmission device 310 may be in-band or out of band communication. According to various embodiments, when using the in-band communication, the power reception device 320 may transmit a data signal, included in a power signal. When the power reception device 320 uses the in-band communication, the second communication circuit 325 may communicate with the power transmission device 310 using the same or adjacent frequency to a frequency used for power transfer in the power transmission device 310. For example, the wireless power consortium (WPC) among international standards may transmit power using a frequency band of about 100 kHz or more to about 200 kHz or less and may communicate using a modulation signal of about 1.5 kHz or more to about 2.5 kHz or less. Data (or a communication signal) generated by the second communication circuit 325 may be transmitted using the receive coil 321. The second communication circuit 325 may deliver data to the power transmission device 310 using an amplitude shift keying (ASK) or frequency shift keying (FSK) modulation scheme. For example, the WPC among international standards may transmit data from the power reception device 320 to the power transmission device 310 in an ASK scheme based on load modulation. For another example, the second communication circuit 325 may communicate with the power transmission device 310 by changing a frequency of a power signal delivered through the receive coil 321. In detail, the second communication circuit 325 may represent data by increasing or decreasing a frequency of the power reception signal.

According to various embodiments, when the power reception device 320 uses the out of band communication, the second communication circuit 325 may communicate with the first communication circuit 317 of the power transmission device 310 using a frequency different from a frequency used for power transfer in the power transmission device 310. For example, the second communication circuit 325 may obtain information (e.g., a voltage value after the rectifier, rectified voltage value (e.g., Vrect) information, information about current flowing in the receive coil 321 or the rectifier 323, various packets, and/or a message) associated with a state of charge from the first communication circuit 317 using any one of various short range communication schemes such as Bluetooth, Bluetooth low energy (BLE), Wi-Fi, or near field communication (NFC). The second communication circuit 325 may deliver data about the rectified voltage Vrect, the rectified current Irect, the output voltage Vout, and the output current Tout to the first communication circuit 317 through wireless communication.

In another embodiment, the sensing circuit 326 may detect the input voltage Vin, the input current Iin, the inverter voltage Vinv, the inverter current Iinv, the rectified voltage Vrect, the rectified current Irect, the output voltage Vout, and the output current Tout. The sensing circuit 326 may transfer the detected input voltage Vin and the detected input current Iin to the controller 316 or the micro controller unit

In yet another embodiment, receiving the input voltage Vin and the input current Iin, the controller 316 or the MCU may calculate a transmit power of the power transmission device 310. For example, the controller 316 or the MCU may multiply a value of the input voltage Vin and a value of the input current Iin to calculate the transmit power of the power transmission device 310. The sensing circuit 326 may deliver a signal including data about the output voltage Vout and the output current Tout to the controller 316 or the MCU. The controller 316 or the MCU may demodulate the signal to calculate a receive power of the power reception device 320. The controller 316 or the MCU may calculate the ratio of the transmit power to the receive power to measure power transmission efficiency of the system 300.

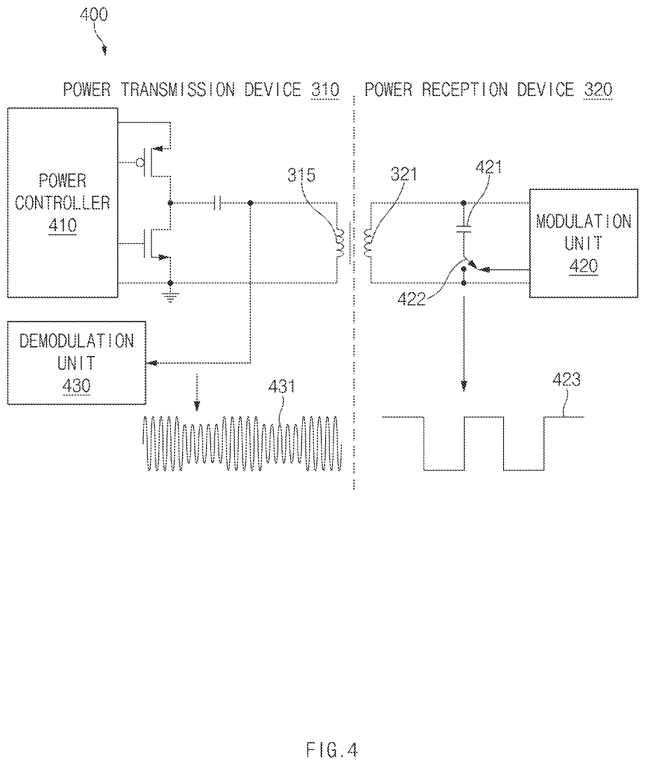

FIG. 4 is a drawing 400 illustrating in-band communication of a wireless charging system set to an international standard in the WPC according to an embodiment of the disclosure.

In an embodiment, a power reception device 320 of the wireless charging system set to the international standard may control a capacitance value of a Iine which transfers AC power in the power reception device 320 to perform in-band communication in the wireless charging system. A capacitor 421 may be disposed in the Iine which transfers the AC power in the power reception device 320.

In another embodiment, the power reception device 320 of the wireless charging system set to the international standard may change a capacitance value of the line which transfers the AC power to change a voltage of a transmit coil 315 of the power transmission device 310. For example, the power reception device 320 may perform an operation of turning on and off a switch 422 connected with the capacitor 421. The power reception device 320 may change a capacitance value of the Iine which transfers the AC power by means of the operation of turning on and off the switch 422. For another example, the capacitor 421 of the power reception device 320 may be a variable capacitor capable of changing a capacitance value. The power reception device 320 may change a capacitance value of the Iine which transfers the AC power to change a voltage of the transmit coil 315 of the power transmission device 310.

In yet another embodiment, the power reception device 320 of the wireless charging system set to the international standard may transmit a signal 423 to the power transmission device 310. A modulation unit 420 of the power reception device 320 may modulate and transmit the signal 423 into a binary code. For example, the signal 423 may be modulated using a clock of about 2 KHz. The signal 423 may include information associated with a change in voltage and capacitance value of a load of the power reception device 320, which is measured by the power reception device 320. The power transmission device 310 may detect the signal 431 in the transmit coil 315. A demodulation unit 430 of the power transmission device 310 may demodulate the signal 431. The power transmission device 310 may control a power controller 410 depending on the change in voltage and capacitance value of the load of the power reception device 320, which are included in the signal 431. The power transmission device 310 may perform a power transmission operation requested by the power reception device 320.

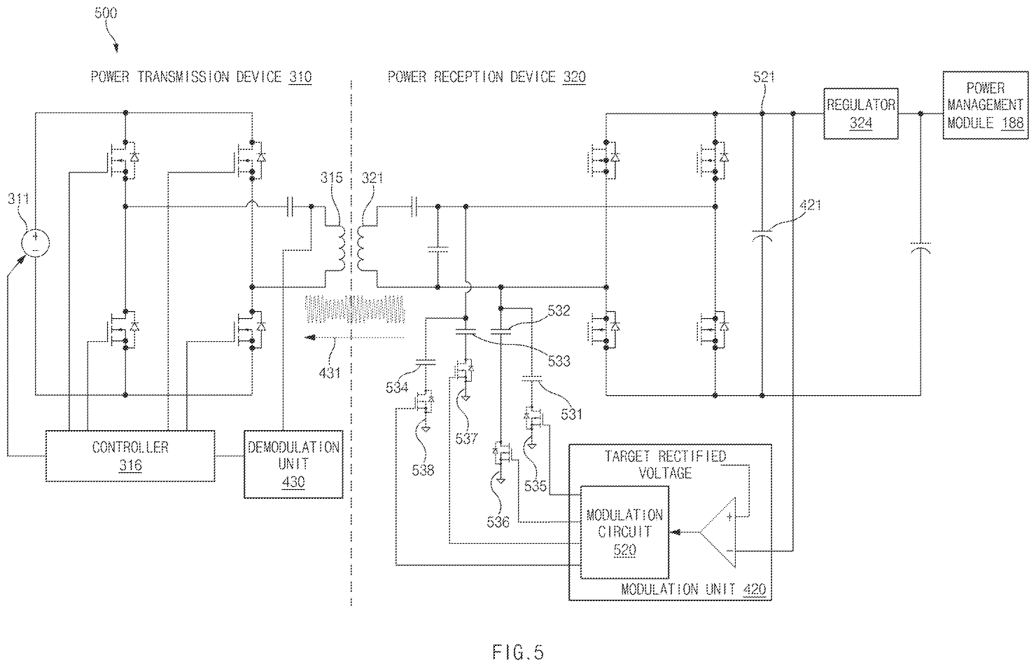

FIG. 5 is a drawing 500 illustrating a wireless charging system set to an international standard in the WPC according to an embodiment of the disclosure.

In an embodiment, a modulation unit 420 of a power reception device 320 of the wireless charging system set to the international standard in the WPC may include a modulation circuit 520. The modulation circuit 520 may measure a rectified current (e.g., Vrect of FIG. 3) supplied to a regulator 324 at a measurement point 521. The rectified voltage may refer to a DC voltage into which an AC voltage received from a coil (e.g., a receive coil 321 of FIG. 3) by a receiver is converted through a rectification stage. The modulation circuit 520 may compare the rectified voltage with a target rectified voltage. The modulation circuit 520 may be connected with Iines which transfer AC power.

Modulation capacitors 531, 532, 533, and 534 may be respectively arranged on Iines which transfer an AC power of a wireless charging system set to the international standard in the WPC. The modulation capacitors 531, 532, 533, and 534 may be connected in parallel with each other. The modulation capacitors 531, 532, 533, and 534 may change capacitance values of the Iines which transfer the AC power. For example, the modulation capacitors 531, 532, 533, and 534 may be connected with switches 535, 536, 537, and 538, respectively. A rectified voltage, which is changed by operations of the switches 535, 536, 537, and 538, may be defined as a modulation voltage. Each of the switches 535, 536, 537, and 538 may be implemented as a MOSFET. The modulation capacitors 531, 532, 533, and 534 and the switches 535, 536, 537, and 538 may make up a capacitor switch network.

In an embodiment, each of the switches 535, 536, 537, and 538 included in the capacitor switch network may be turned on or off according to a control signal to change a connection state between the modulation circuit 520 and the modulation capacitors 531, 532, 533, and 534. In another embodiment, as each of the switches 535, 536, 537, and 538 is turned on or off, it may change capacitance values of the Iines which transfer the AC power. For another example, each of the modulation capacitors 531, 532, 533, and 534 may be implemented as a variable capacitor. When each of modulation capacitors 531, 532, 533, and 534 is the variable capacitor, its capacitance value may be changed under control of a micro controller unit (MCU) (e.g., a processor 120 of FIG. 3) of the power reception device 320.

When a capacitance value formed by the modulation capacitors 531, 532, 533, and 534 is changed when modulating a signal for in-band communication, the rectified voltage may be changed. The change in rectified voltage may be determined by at least one or more elements among a characteristic of the transmit coil 315 of the power transmission device 310, a characteristic of a receive coil 321 of the power reception device 320, a change in correlation according to alignment of the transmit coil 315 and the receive coil 321, resonance settings of the transmit coil 315 and the receive coil 321, an output current (e.g., an output current lout of FIG. 3) of the power reception device 320, and an inverter voltage (e.g., an inverter voltage Vinv of FIG. 3) of an inverter (e.g., an inverter 313 of FIG. 3) of the power transmission device 310.

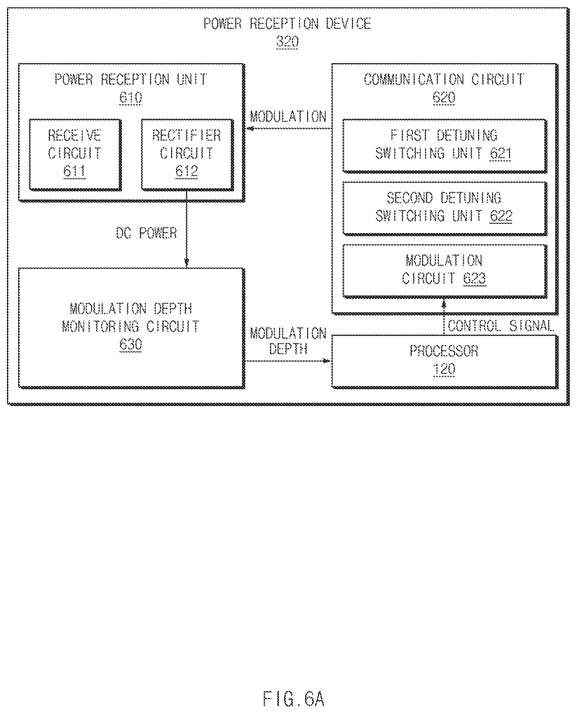

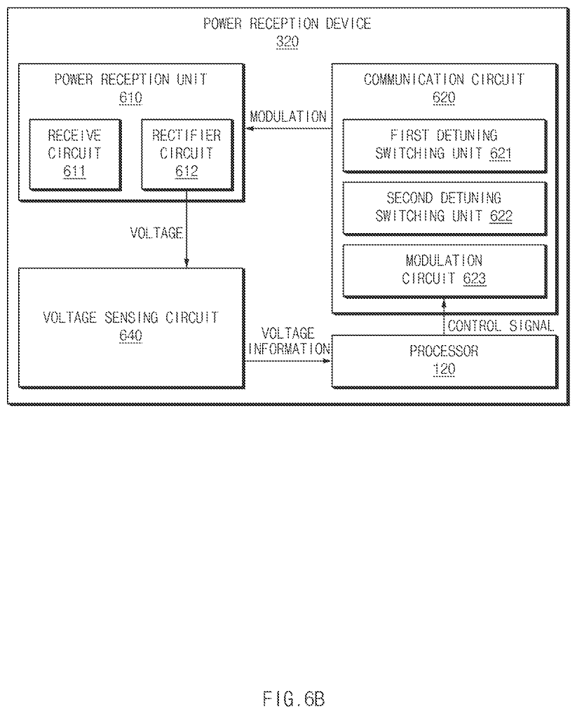

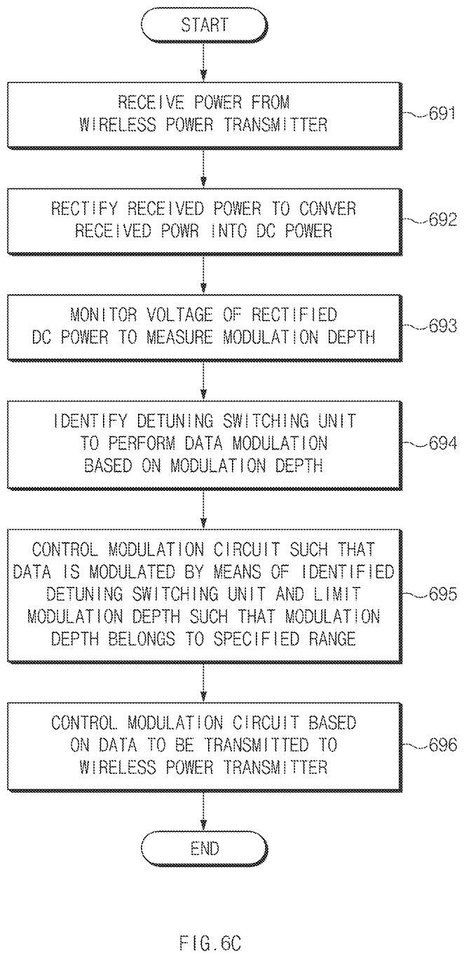

FIG. 6A is a block diagram illustrating a power reception device 320 according to an embodiment of the disclosure. A power reception device 320 may include a power reception unit (i.e., circuitry) 610, a communication circuit 620 (e.g., a second communication circuit 325 of FIG. 3), a modulation depth monitoring circuit 630, and a processor 120.

In an embodiment, the power reception unit 610 may receive power from a wireless power transmitter (e.g., a power transmission device 310 of FIGS. 3 to 5) and may rectify the received power to convert the received power into DC power. The power reception unit 610 may include a receive circuit 611 and a rectifier circuit 612 (e.g., a rectifier 323 of FIG. 3).

In another embodiment, the reception circuit 611 may receive power from the wireless power transmitter 310. The receive circuit 611 may include a coil (e.g., a receive coil 321 of FIG. 3) and a first capacitor (e.g., a second matching unit 322 of FIG. 3). The coil 321 may wirelessly receive power. The first capacitor may match an input impedance of the receive circuit 611 with an internal impedance of the receive circuit 611.

In yet another embodiment, the rectifier circuit 612 may rectify the power received by the receive circuit 611. The rectifier circuit 612 may convert the power received by the receive circuit 611 into DC power.

In an embodiment, the communication circuit 620 may perform modulation of changing a voltage of the power received in the coil 321. The communication circuit 620 may turn on or off modulation based on the received control signal. The communication circuit 620 may include a first detuning switching unit (i.e., circuitry) 621, a second detuning switching unit (i.e., circuitry) 622, and a modulation circuit 623. It is shown that there are two detuning switching units 621 and 622 in FIG. 6A. However, it is not limited thereto. The communication circuit 620 may include a plurality of detuning switching units 621 and 622.

In another embodiment, each of the detuning switching unit 621 and the second detuning switching unit 622 may include a second capacitor and a switch. Each of the first detuning switching unit 621 and the second detuning switching unit 622 may change a voltage of the power received in the coil 321.

In yet another embodiment, the modulation circuit 623 may turn on or off the switch based on the control signal received from the processor 120.

In an embodiment, the modulation depth monitoring circuit 630 may monitor the rectified DC power. The modulation depth monitoring circuit 630 may monitor a voltage of the rectified DC power. The modulation depth monitoring circuit 630 may measure a modulation depth based on the monitored voltage. The modulation depth monitoring circuit 630 may provide the processor 120 with the measured modulation depth.

In another embodiment, the processor 120 may receive the modulation depth from the modulation depth monitoring circuit 630. The processor 120 may identify a detuning switching unit to perform data modulation among the plurality of detuning switching units 621 and 622 based on the modulation depth. For example, when the modulation depth corresponds to a modulation depth range using the first detuning switching unit 621, the processor 120 may determine the first detuning switching unit 621 as a detuning switching unit to perform data modulation.

In yet another embodiment, the processor 120 may control the modulation circuit 623 such that data is modulated by means of the identified detuning switching unit. The processor 120 may limit a modulation depth such that the modulation depth belongs to a specified range. The processor 120 may transmit a control signal to the modulation circuit 623. The control signal may turn on or off the switch of each of the plurality of detuning switching units 621 and 622. For example, when determining the first detuning switching unit 621 as the detuning switching unit to perform the data modulation, the processor 120 may transmit a control signal for turning on the switch of the first detuning switching unit 621 and turning off the switch of the second detuning switching unit 622 to the modulation circuit 623.

In an embodiment, the processor 120 may control the modulation circuit 623 based on data to be transmitted to the wireless power transmitter 310.

FIG. 6B is a block diagram illustrating a power reception device 320 according to an embodiment of the disclosure. A power reception device 320 may include a power reception unit 610, a communication circuit 620, a voltage sensing circuit 640, and a processor 120. The power reception unit 610 and the communication circuit 620 of the power reception device 320 according to FIG. 6B may be substantially the same as a power reception unit 610 and a communication circuit 620 of a power reception device 320 according to FIG. 6A.

In an embodiment, the voltage sensing circuit 640 may sense the DC power rectified by a rectifier circuit 612. The voltage sensing circuit 640 may sense a voltage of the rectified DC power. The voltage sensing circuit 640 may provide the processor 120 with the sensed voltage information.

In another embodiment, the processor 120 may receive the voltage information sensed by the voltage sensing circuit 640. The processor 120 may calculate a modulation depth based on the received voltage information. The processor 120 may identify a detuning switching unit to perform data modulation among a plurality of detuning switching units 621 and 622 based on the modulation depth. The processor 120 may control the modulation circuit 623 such that data is modulated by means of the identified detuning switching unit. The processor 120 may limit a modulation depth such that the modulation depth belongs to a specified range.

FIG. 6C a flowchart illustrating a method for controlling charging of a power reception device 320 according to an embodiment of the disclosure.

In operation 691, the power reception device 320, according to an embodiment, may receive power from a wireless power transmitter (e.g., a power transmission device 310 of FIGS. 3 to 5).

In operation 692, the power reception device 320, according to an embodiment, may rectify the received power to convert the received power into DC power.

In an embodiment, the power reception device 320 may perform in-band communication to modulate a switching circuit. For example, the switching circuit may include switches included in a capacitor switch network shown in FIG. 5. A processor 120 of the power reception device 320 may open or close the switches included in the switching circuit. For another example, when modulation capacitors 531, 532, 533, and 534 included in the capacitor switch network shown in FIG. 5 are variable capacitors, the switching circuit may change a capacitance value of the variable capacitor. The processor 120 of the power reception device 320 may control the switching circuit to change the capacitance value of the variable capacitor. The switching circuit may vary a capacitance value in a previous stage of a rectifier (e.g., a rectifier 323 of FIG. 3) to modulate a signal for in-band communication.

In operation 693, the power reception device 320, according to an embodiment, may monitor a voltage of the rectified DC voltage to measure a modulation depth.

In another embodiment, the power reception device 320 may monitor a modulation depth which is a difference value between a magnitude of a rectified voltage when the switching circuit turns on modulation and a magnitude of a rectified voltage when the switching circuit turns off modulation. The modulation depth may be changed by various factors. For example, a modulation direction and/or a modulation magnitude in the modulation depth may be changed by a mutual inductance between a transmit coil (e.g., a transmit coil 315 of FIG. 3) and a receive coil (e.g., a receive coil 321 of FIG. 3) in which wireless charging proceeds, a coupling k value between the transmit coil 315 and the receive coil 321, a load current of a power reception unit (e.g., a power reception unit 610 of FIG. 6A and/or FIG. 6B), an operating frequency of the receive coil 321, a resonant capacitance of a wireless power transmitter (e.g., a power transmission device 310 of FIGS. 3 to 5), an inductance of the transmit coil 315, a resonant capacitance of the power reception unit 610, an inductance of the receive coil 321, and/or a voltage applied to an inverter (e.g., an inverter 313 of FIG. 3) of the wireless power transmitter 310. A difference may occur between a rectified voltage when the switching circuit turns on modulation and a rectified voltage when the switching circuit turns off modulation. The difference value between the magnitude of the rectified voltage when the switching circuit turns on the modulation and the magnitude of the rectified voltage when the switching circuit turns off the modulation may be defined as a modulation depth.

For example, when the switching circuit closes a switch connected with the capacitor to change a capacitance value in the front stage of the rectifier 323 of the power reception device 320, the switching circuit may turn on modulation. As such, when the switching circuit turns on the modulation, the modulation of the signal may be enabled. For another example, when opening the switch connected with the capacitor, the switching circuit may turn off the modulation. As such, when the switching circuit turns off the modulation, the modulation of the signal may be disabled.

When the modulation depth increases, audible noise may occur upon modulation of the signal. The larger the change in capacitance values formed by modulation capacitors (e.g., modulation capacitors 531, 532, 533, and 534 of FIG. 5), the more the change width of the rectified voltage in the previous stage of the rectifier 323 of the power reception device 320 may increase. For example, the more the change width of the rectified voltage in the previous stage of the rectifier 323 of the power reception device 320, the more the noise of the audible frequency band of 2 KHz which is a frequency band used for modulation may occur.

In operation 694, the power reception device 320, according to an embodiment, may identify a detuning switching unit to perform data modulation based on the modulation depth.

In operation 695, the power reception device 320, according to an embodiment, may control the modulation circuit such that data is modulated by means of the identified detuning switching unit and may limit a modulation depth such that the modulation depth belongs to a specified range.

In yet another embodiment, the power reception device 320 may select any one of a plurality of capacitance values such that the modulation depth belongs to the specified range. The processor 120 of the power reception device 320 may control a capacitance value formed by the modulation capacitors 531, 532, 533, and 534. The processor 120 may dynamically vary the capacitance value and may control a rectified voltage such that a difference value between magnitudes of the rectified voltage when turning on and off modulation belongs to the specified range.

In an embodiment, the power reception device 320, according to an embodiment, may make up a feedback system for controlling a modulation depth, which is a difference upon modulation on/off of the rectified voltage of the power reception device 320 due to a change in capacitance upon modulation for wireless charging, within the specified range. Thus, the processor 120 may reduce audible noise which is generated in the previous stage of the rectifier 323 upon modulation for in-band communication.

The power reception device 320, according to an embodiment, may prepare to implement a plurality of capacitance values selectable to dynamically vary the capacitance value. For example, the power reception device 320 may store the plurality of selectable capacitance values in the form of a look up table (LUT) in a memory (e.g., a memory 130 of FIG. 1). For another example, the power reception device 320 may store a method for controlling a switching circuit to implement a capacitance value to be selected among the plurality of capacitance values in the memory 130. The method for controlling the plurality of selectable capacitance values in the form of the LUT stored in the memory 130 or the switching circuit may be referred to as a modulation control table.

In operation 696, the power reception device 320, according to an embodiment, may control the modulation circuit (e.g., the modulation circuit 623 of FIG. 6A and/or FIG. 6B) based on data to be transmitted to the wireless power transmitter 310.

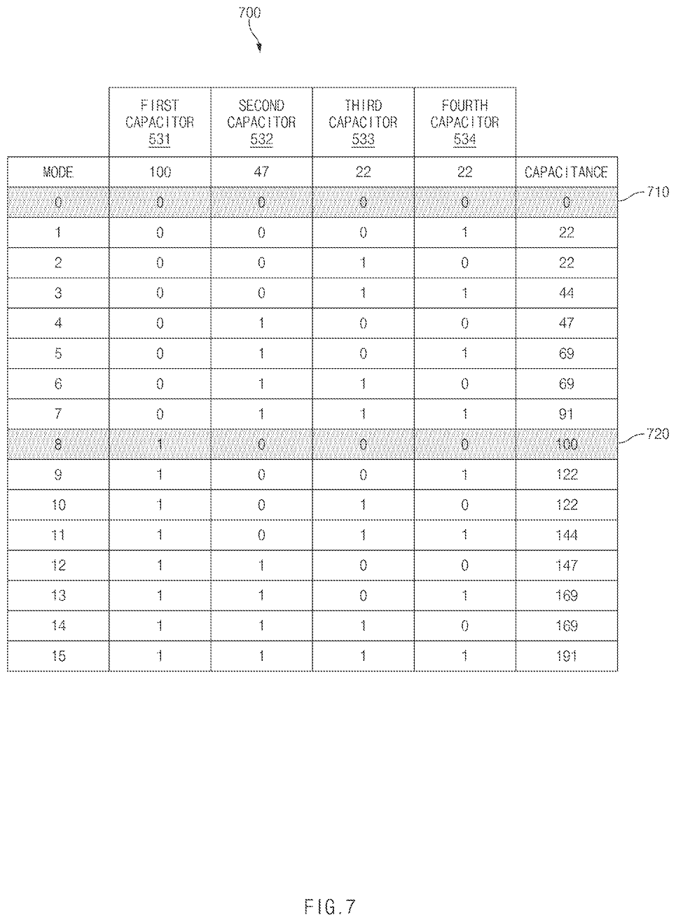

FIG. 7 is a table 700 illustrating a modulation control table according to an embodiment of the disclosure.

In an embodiment, the modulation control table may include information about a capacitance value of each of modulation capacitors 531, 532, 533, and 534, a plurality of modes according to whether each of the modulation capacitors 531, 532, 533, and 534 is used, and a total capacitance value formed by the modulation capacitors 531, 532, 533, and 534.

In another embodiment, the capacitance value of each of the modulation capacitors 531, 532, 533, and 534 may be set to values capable of implementing a plurality of capacitance values to be implemented. For example, as shown in FIG. 7, when implementing a plurality of capacitance values having values of 22 or more and 191 or less, the first capacitor 531 among the modulation capacitors 531, 532, 533, and 534 may have a value of 100 nF, the second capacitor 532 may have a value of 47 nF, the third capacitor 533 may have a value of 22 nF, and the fourth capacitor 534 may have a value of 22 nF. The capacitance value may have a value of 1 nF or more and 1 μF or less. For example, the plurality of capacitance values shown in FIG. 7 may be greater than or equal to 22 nF and is less than or equal to 191 nF.

In yet another embodiment, when the number of the modulation capacitors 531, 532, 533, and 534 is n (where n is a natural number), modes according to whether each of the modulation capacitors 531, 532, 533, and 534 is used may be a total of 2\hat{ }n. For example, when the number of the modulation capacitors 531, 532, 533, and 534 is four, the modes according to whether each of the modulation capacitors 531, 532, 533, and 534 is used may be a total of 16. Whether each of the modulation capacitors 531, 532, 533, and 534 is used may be whether a switch connected with each of the modulation capacitors 531, 532, 533, and 534 is turned on or off. In FIG. 7, the case where the switch connected with each of the modulation capacitors 531, 532, 533, and 534 is turned on is displayed as 1, and the case where the switch connected with each of the modulation capacitors 531, 532, 533, and 534 is turned off is displayed as 0.

In an embodiment, the total capacitance value may be a capacitance value formed by a capacitor in which the connected switch is turned on among the modulation capacitors 531, 532, 533, and 534. For example, when all of the switch connected with the first capacitor 531, the switch connected with the second capacitor 532, the switch connected with the third capacitor 533, and the switch connected with the fourth capacitor 534 are turned off like an off mode 710, the total capacitance value may be 0. For another example, when the switch connected with the first capacitor 531 is turned on and when the switch connected with the second capacitor 532, the switch connected with the third capacitor 533, and the switch connected with the fourth capacitor 534 are turned off like a default mode 720, the total capacitance value may be 100. For another example, when the switch connected with the second capacitor 532 and the switch connected with the third capacitor 533 are turned on and when the switch connected with the first capacitor 531 and the switch connected with the fourth capacitor 534 are turned off, the total capacitance value may be 69.

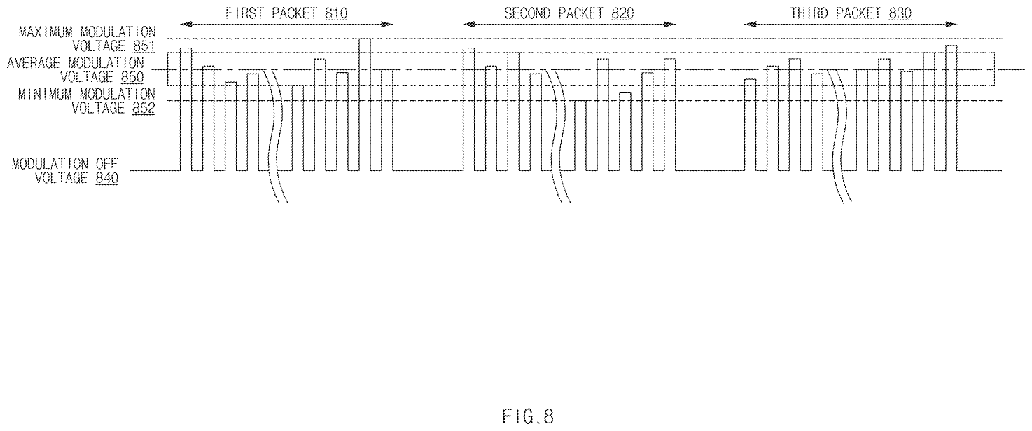

In another embodiment, the modulation control table may be configured such that the capacitance value changed upon modulation increases as an upper value changes. A setting of increasing a capacitance value may correspond to a task of adjusting a modulation setting value to an upper value. Hereinafter, an increase in capacitance value in FIGS. 8, 9, 10A to 10D, 11A to 11D, and 12 may correspond to an operation of adjusting a modulation setting value (e.g., a mode setting value) to an upper value. For example, when changing whether the second capacitor 532 which is an upper value than the third capacitor 533 is used, the capacitance value changed upon modulation may increase from 22 to 47. For another example, when changing whether the first capacitor 531 which is an upper value than the second capacitor 532 is used, the capacitance value changed upon modulation may increase from 47 to 100.

FIG. 8 is a graph 800 illustrating calculating an average value of the modulation depth according to an embodiment of the disclosure. In other words, the rectified voltage includes both of a modulation off voltage and a modulation voltage described in the specification, and the modulation voltage refers to only the modulation voltage except for the modulation off voltage.

In an embodiment, a processor 120 of a power reception device 320 may calculate an average value of the modulation depth for each packet. The packet may refer to a unit where communication data is transmitted. The processor 120 may calculate a magnitude of a modulation voltage for each of a first packet 810, a second packet 820, and a third packet 830.

In another embodiment, the rectified voltage may include a modulation off voltage 840, an average modulation voltage 850, a maximum modulation voltage 851, and a minimum modulation voltage 852. The modulation voltage may include the average modulation voltage 850, the maximum modulation voltage 851, and the minimum modulation voltage 852 except for the modulation off voltage 840.

In yet another embodiment, the processor 120 may calculate an average value of the modulation depth for each packet. The processor 120 may calculate a magnitude of the average modulation voltage 850 on the basis of the modulation off voltage 840 which is a modulation voltage in a state where all switches are turned off

In an embodiment, the processor 120 may determine whether the magnitude of the average modulation voltage 850 belongs to a range between the maximum modulation voltage 851 and the minimum modulation voltage 852. The maximum modulation voltage 851 and the minimum modulation voltage 852 may be pre-setting voltage values. In an embodiment, the maximum modulation voltage 851 and the minimum modulation voltage 852 may be values set according to an application. For example, the maximum modulation voltage 851 and the minimum modulation voltage 852 may be values preset according to a function performed in the application. The processor 120 may control the modulation voltage such that the magnitude of the average modulation voltage 850 belongs to a range between the maximum modulation voltage 851 and the minimum modulation voltage 852.

In another embodiment, when packet modulation occurs as wireless charging is started, the processor 120 may measure a modulation depth for respective packets to calculate an average value. The processor 120 may take an average of the sum of values measured for every packet to calculate an average value of the modulation depth.

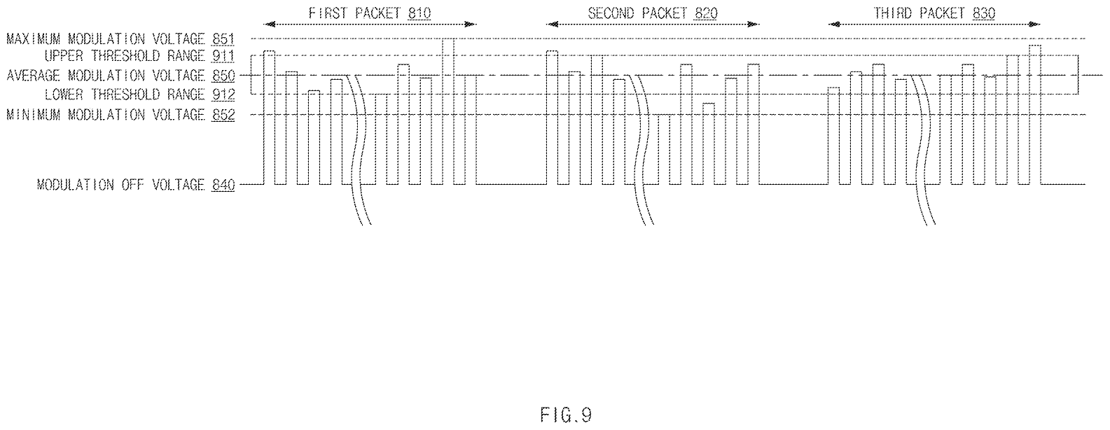

FIG. 9 is a graph 900 illustrating calculating an average value of the modulation depth according to an embodiment of the disclosure.

In an embodiment, a processor 120 of a power reception device 320 may calculate a magnitude of a modulation voltage for each of a first packet 810, a second packet 820, and a third packet 830.

In another embodiment, the processor 120 may calculate an average value of the modulation depth for each packet. The processor 120 may calculate a magnitude of an average modulation voltage 850 on the basis of a modulation off voltage 840 which is a modulation voltage in a state where all switches are turned off

In yet another embodiment, the processor 120 may use a modulation voltage having a value between an upper threshold range 911 and a lower threshold range 912, when calculating the average modulation voltage 850. The processor 120 may exclude a modulation voltage deviating from the upper threshold range 911 and the lower threshold range 912, when calculating the average modulation voltage 850. For example, the upper threshold range 911 and the lower threshold range 912 may be set within a specified range (or rate).

In an embodiment, when packet modulation occurs as wireless charging is started, the processor 120 may measure a modulation depth for respective packets to calculate an average value. The processor 120 may take an average value of the other samples except for an upper certain rate and a lower certain rate among all sample values taking an average to calculate an average value of the modulation depth. Thus, the processor 120 may improve accuracy of the average value of the modulation depth.

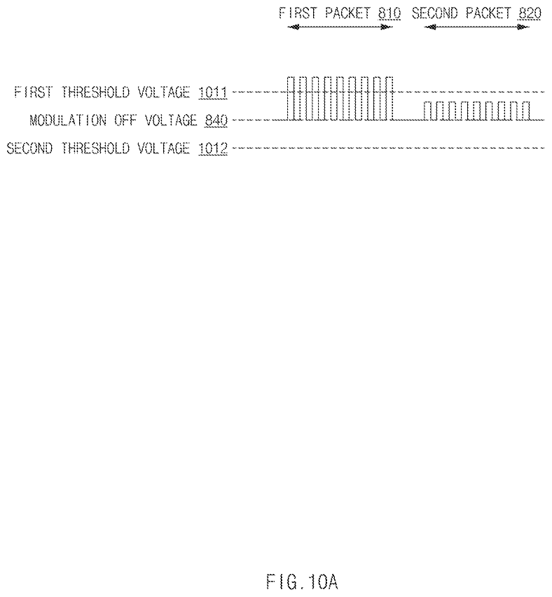

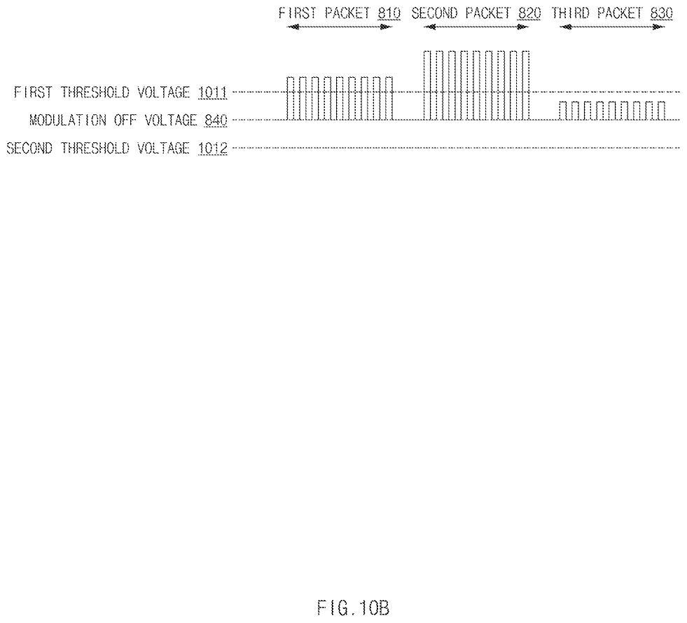

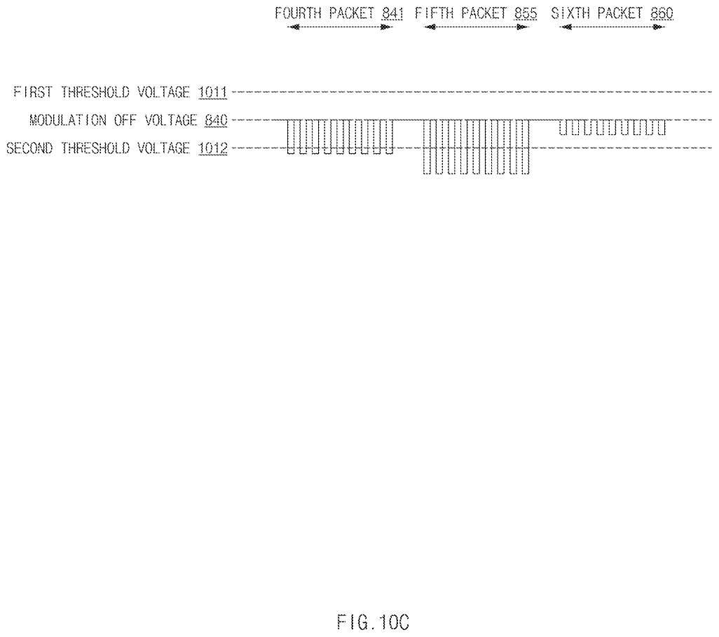

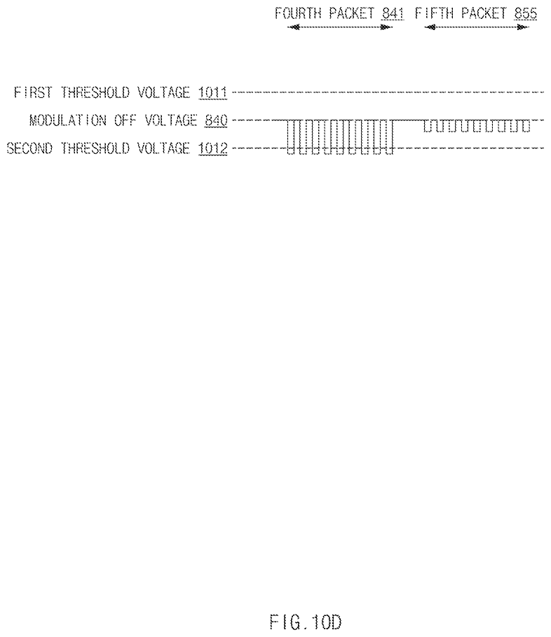

FIG. 10A is a graph illustrating a change in modulation voltage when controlling a modulation depth according to an embodiment of the disclosure. FIG. 10B is a graph illustrating a change in modulation voltage when controlling a modulation depth according to an embodiment of the disclosure. FIG. 10C is a graph illustrating a change in modulation voltage when controlling a modulation depth according to an embodiment of the disclosure. FIG. 10D is a graph illustrating a change in modulation voltage when controlling a modulation depth according to an embodiment of the disclosure.

In an embodiment, a processor 120 of a power reception device 320 may control a magnitude of a modulation voltage for each of a first packet 810, a second packet 820, a third packet 830, a fourth packet 841, a fifth packet 855, and a sixth packet 860. The processor 120 may perform comparison with a magnitude of a modulation off voltage 840 to control the magnitude of the modulation voltage.

In another embodiment, controlling a modulation depth in FIGS. 10A, 10B, 10C, and 10D may independently proceed.

In yet another embodiment, FIG. 10A illustrates performing control of the modulation voltage once when the modulation voltage is greater than or equal to a first threshold voltage 1011 to control the modulation voltage to the first threshold voltage 1011 or less.

In an embodiment, for upward modulation when the modulation voltage is higher than the modulation off voltage 840, when a magnitude of the modulation voltage during any one packet is greater than or equal to the first threshold voltage 1011, the processor 120 may adjust a modulation setting value to a lower value to reduce a modulation voltage of a next packet. The first threshold voltage 1011 may be a value higher than the modulation off voltage 840 by a specified value. For example, the first threshold voltage 1011 may be a value higher than the modulation off voltage 840 by about 100 mV. For example, because the magnitude of the modulation voltage of the first packet 810 is greater than or equal to the first threshold voltage 1011, the processor 120 may adjust the modulation setting value to the lower value to decrease the magnitude of the modulation voltage of the second packet 820 to the first threshold voltage 1011 or less.

In another embodiment, FIG. 10B illustrates performing control of the modulation voltage two times when the modulation voltage is greater than or equal to the first threshold voltage 1011 to control the modulation voltage to the first threshold voltage 1011 or less.

In yet another embodiment, for upward modulation when the modulation voltage is higher than the modulation off voltage 840, when a magnitude of the modulation voltage during any one packet is greater than or equal to the first threshold voltage 1011, the processor 120 may adjust a modulation setting value to a lower value to reduce a modulation voltage of a next packet. The first threshold voltage 1011 may be a value higher than the modulation off voltage 840 by a specified value. For example, the first threshold voltage 1011 may be a value higher than the modulation off voltage 840 by about 100 mV. For example, because the magnitude of the modulation voltage of the first packet 810 is greater than or equal to the first threshold voltage 1011, the processor 120 may adjust the modulation setting value to the lower value to decrease the magnitude of the modulation voltage of the second packet 820.

In an embodiment, when the magnitude of the modulation voltage is greater than or equal to the first threshold voltage 1011 and when the modulation voltage continues increasing, the processor 120 may additionally adjust the modulation setting value to decrease a magnitude of a modulation voltage of a next packet (e.g., a third packet 830) to the first threshold voltage 1011 or less. For example, when the magnitude of the modulation voltage of the second packet 820 is greater than or equal to the first threshold voltage 1011 and when the modulation voltage continues increasing, the processor 120 may additionally adjust the modulation setting value to an upper value to decrease the magnitude of the modulation voltage of the third packet 830 to the first threshold voltage 1011 or less.

In another embodiment, FIG. 10C illustrates performing control of the modulation voltage once when the modulation voltage is less than or equal to the second threshold voltage 1012 to control the modulation voltage to the second threshold voltage 1012 or more.

In yet another embodiment, when a magnitude of a modulation voltage during any one packet is less than or equal to the second threshold voltage 1012, the processor 120 may adjust the modulation setting value to an upper value to increase a modulation voltage of a next packet. For example, when the magnitude of the modulation voltage of the fourth packet 841 is less than or equal to the second threshold voltage 1012, the processor 120 may adjust the modulation setting value to an upper value to increase a modulation voltage of a next packet to the second threshold voltage 1012 or more.

In an embodiment, FIG. 10D illustrates performing control of the modulation voltage two times when the modulation voltage is less than or equal to the second threshold voltage 1012 to control the modulation voltage to the second threshold voltage 1012 or more.

In another embodiment, for downward modulation when the modulation voltage is lower than the modulation off voltage 840, when a magnitude of the modulation voltage during any one packet is less than or equal to the second threshold voltage 1012, the processor 120 may adjust the modulation setting value to an upper value to increase a modulation voltage of a next packet to the second threshold voltage 1012 or more. The second threshold voltage 1012 may be a value lower than the modulation off voltage 840 by a specified value. For example, the second threshold voltage 1012 may be a value lower than the modulation off voltage 840 by about 100 mV. For example, because the magnitude of the modulation voltage of the fourth packet 841 is less than or equal to the second threshold voltage 1012, the processor 120 may adjust the modulation setting value to an upper value to increase the magnitude of the modulation voltage of the fifth packet 855 to the second threshold voltage 1012 or more.

In yet another embodiment, when the magnitude of the modulation voltage is less than or equal to the second threshold voltage 1012 and when the modulation voltage continues decreasing, the processor 120 may additionally adjust the modulation setting value to increase a magnitude of a next modulation voltage. For example, the processor 120 may detect that the magnitude of the modulation voltage of the fifth packet 855 is less than or equal to the second threshold voltage 1012 and that the modulation voltage continues decreasing. When the level of the fifth packet 855 more decreases to the second threshold voltage or less although the modulation setting value is set to the upper value to increase the level of the fourth packet 841 to the second threshold voltage or more, the processor 120 may additionally adjust the modulation setting value to a lower value to increase the magnitude of the modulation voltage of the sixth packet 860 to the second threshold voltage 1012 or more.

In an embodiment, the processor 120 may perform a modulation depth control operation. The processor 120 may maintain an average value of the modulation depth for the plurality of packets within a specified range. The processor 120 may set a modulation control table to maintain the average value of the modulation depth within the specified range.

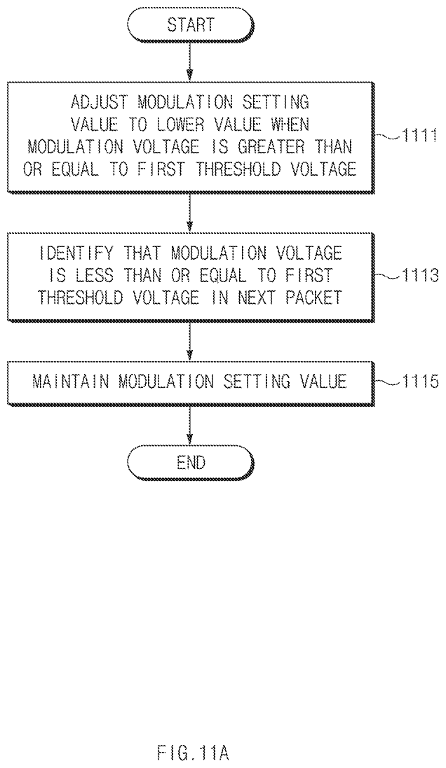

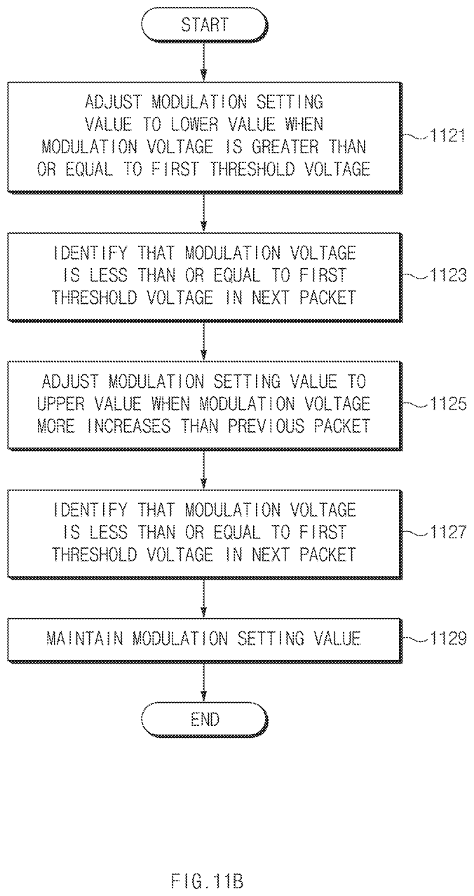

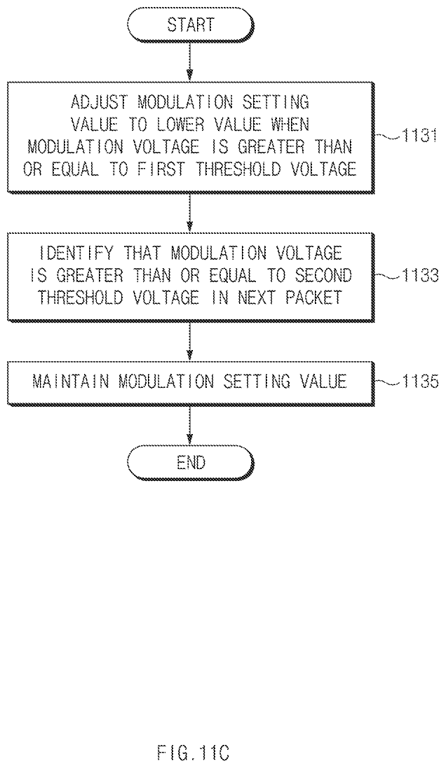

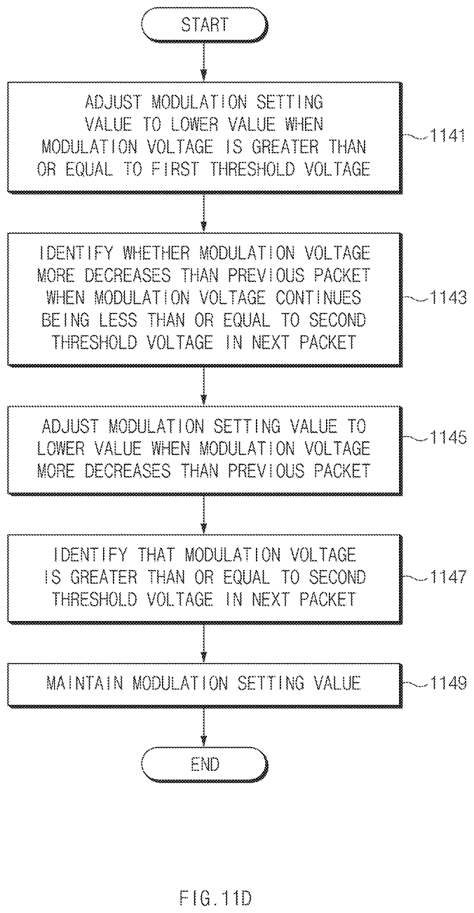

FIG. 11A is a flowchart illustrating a method for controlling a modulation depth to control a modulation voltage according to an embodiment of the disclosure. FIG. 11B is a flowchart illustrating a method for controlling a modulation depth to control a modulation voltage according to an embodiment of the disclosure. FIG. 11C is a flowchart illustrating a method for controlling a modulation depth to control a modulation voltage according to an embodiment of the disclosure. FIG. 11D is a flowchart illustrating a method for controlling a modulation depth to control a modulation voltage according to an embodiment of the disclosure.

In an embodiment, controlling a modulation depth in FIGS. 11A, 11B, 11C, and 11D may independently proceed.

In another embodiment, FIG. 11A illustrates performing control of the modulation voltage once when the modulation voltage is greater than or equal to a first threshold voltage 1011 to control the modulation voltage to the first threshold voltage 1011 or less. The case of FIG. 11A may correspond to the case corresponding to FIG. 10A.

In operation 1111, a processor (e.g., a processor 120 of FIG. 3) of a power reception device 320, according to an embodiment, may adjust a modulation setting value to a lower value, when the modulation voltage is greater than or equal to a first threshold voltage. When an average modulation voltage value of any one packet is greater than or equal to the first threshold voltage, the processor 120 may change a module setting value to one lower value. When the average modulation voltage value of the any one packet is greater than or equal to the first threshold voltage, the processor 120 may set the modulation control table to one lower mode to select one lower value than a value previously selected among a plurality of capacitance values. The processor 120 may change the selected mode to a lower mode to reduce the set capacitance value.

In operation 1113, the processor 120, according to an embodiment, may identify that the modulation voltage is less than or equal to a first threshold voltage in a next packet. In another embodiment, the processor 120 may identify that the modulation voltage changes to belong to a specified range as the modulation setting value is set.

In operation 1115, the processor 120, according to an embodiment, may maintain the modulation setting value. In another embodiment, the processor 120 may identify that the adjustment of the modulation setting value is performed in a correct direction and may perform modulation using the adjusted modulation setting value.

In yet another embodiment, FIG. 11B illustrates performing control of the modulation voltage two times when the modulation voltage is greater than or equal to the first threshold voltage 1011 to control the modulation voltage to the first threshold voltage 1011 or less. The case of FIG. 11B may correspond to the case corresponding to FIG. 10B.

In operation 1121, the processor (e.g., the processor 120 of FIG. 3) of the power reception device 320, according to an embodiment, may adjust a modulation setting value to a lower value, when the modulation voltage is greater than or equal to a first threshold voltage.

In operation 1123, the processor 120, according to an embodiment, may identify that the modulation voltage more increases than a previous packet, when the modulation voltage continues being greater than or equal to the first threshold voltage in a next packet.

In an embodiment, it may be identified whether the modulation voltage is greater than or equal to the first threshold voltage and whether the modulation voltage more increases than the previous packet (e.g., whether the modulation voltages continues being greater than or equal to the first threshold voltage). When the modulation voltage is greater than or equal to the first threshold voltage and when the modulation voltage more increases than the previous packet, the processor 120 may control the modulation voltage such that the modulation voltage does not deviate from a specified range. A change direction and magnitude of the modulation voltage may vary with a combination of several elements. For example, unlike a direction where the modulation voltage is generally changed upon modulation in a load interval, the direction where the modulation voltage is changed may be reversed in a specific load.

In another embodiment, the processor 120 may read an average value of modulation voltages of the plurality of packets to increase reliability of measurement values referenced to adjust the modulation setting value. For example, the processor 120 may read an average value of modulation voltages of next three packets. When the average value of the modulation voltages of the next three packets is higher than an average value of modulation voltages previously read, the processor 120 may change the mode setting value to one higher value. The processor 120 may set the modulation control table to one upper mode to select one upper value than a value previously selected among a plurality of capacitance values. The processor 120 may change the selected mode to an upper mode to increase the set capacitance value.

In operation 1125, the processor 120, according to an embodiment, may adjust the modulation setting value to an upper value, when the modulation voltage is greater than the first threshold voltage and when the modulation voltage more increases than the previous packet. In another embodiment, the processor 120 may set the modulation control table to one upper mode to select one upper value than a value previously selected among the plurality of capacitance values. The processor 120 may change the selected mode to an upper mode to increase the set capacitance value.

In operation 1127, the processor 120, according to an embodiment, may identify that the modulation voltage is less than or equal to the first threshold voltage in a next packet. In another embodiment, the processor 120 may identify that the modulation voltage changes to belong to a specified range as the modulation setting value is set.

In operation 1129, the processor 120, according to an embodiment, may maintain the modulation setting value. In another embodiment, the processor 120 may identify that the adjustment of the modulation setting value is performed in a correct direction and may perform modulation using the adjusted modulation setting value.

In yet another embodiment, FIG. 11C illustrates performing control of the modulation voltage once when the modulation voltage is less than or equal to the second threshold voltage 1012 to control the modulation voltage to the second threshold voltage 1012 or more. The case of FIG. 11C may correspond to the case corresponding to FIG. 10C.

In operation 1131, the processor (e.g., the processor 120 of FIG. 3) of the power reception device 320, according to an embodiment, may adjust a modulation setting value to an upper value, when the modulation voltage is less than or equal to the second threshold voltage.

In operation 1133, the processor 120, according to an embodiment, may identify that the modulation voltage is greater than or equal to the second threshold voltage in a next packet. In another embodiment, the processor 120 may identify that the modulation voltage changes to belong to a specified range as the modulation setting value is set.

In operation 1135, the processor, 120 according to an embodiment, may maintain the modulation setting value. In another embodiment, the processor 120 may identify that the adjustment of the modulation setting value is performed in a correct direction and may perform modulation using the adjusted modulation setting value.

In an embodiment, FIG. 11D illustrates performing control of the modulation voltage two times when the modulation voltage is less than or equal to the second threshold voltage 1012 to control the modulation voltage to the second threshold voltage 1012 or more. The case of FIG. 11D may correspond to the case corresponding to FIG. 10D.

In operation 1141, the processor (e.g., the processor 120 of FIG. 3) of the power reception device 320, according to an embodiment, may adjust a modulation setting value to an upper value, when the modulation voltage is less than or equal to the second threshold voltage.

In operation 1143, the processor 120, according to an embodiment, may identify that the modulation voltage more decreases than a previous packet, when the modulation voltage continues being less than or equal to the second threshold voltage in a next packet.

In another embodiment, in operation 1145, the processor 120 may adjust the modulation setting value to a lower value, when the modulation voltage more decreases than the previous packet. When the modulation voltage decreases in the next packet, the processor 120 may control the modulation voltage such that the modulation voltage does not deviate from a specified range. For example, the processor 120 may read an average value of modulation voltages of next three packets. When the average value of the modulation voltages of the next three packets is lower than an average value of modulation voltages previously read, the processor 120 may change the mode setting value to one lower value. The processor 120 may set the modulation control table to one lower mode to set the modulation setting value to a modulation setting value before being adjusted to the upper value in operation 1141. The processor 120 may change the selected mode to a lower mode to increase the set capacitance value.

In operation 1147, the processor 120, according to an embodiment, may identify that the modulation voltage is greater than or equal to the second threshold voltage in a next packet. In another embodiment, the processor 120 may identify that the modulation voltage changes to belong to a specified range as the modulation setting value is set.

In operation 1149, the processor 120, according to an embodiment, may maintain the modulation setting value. In another embodiment, the processor 120 may identify that the adjustment of the modulation setting value is performed in a correct direction and may perform modulation using the adjusted modulation setting value.

While repeating operations 1111 to 1149 described in FIGS. 11A to 11D, the processor 120, according to an embodiment, may control a rectified voltage such that the modulation depth belongs to a specified range. In another embodiment, the processor 120 may repeat operations 1111 to 1149. The processor 120 may control the rectified voltage to the first threshold voltage or less and the second threshold voltage or more.

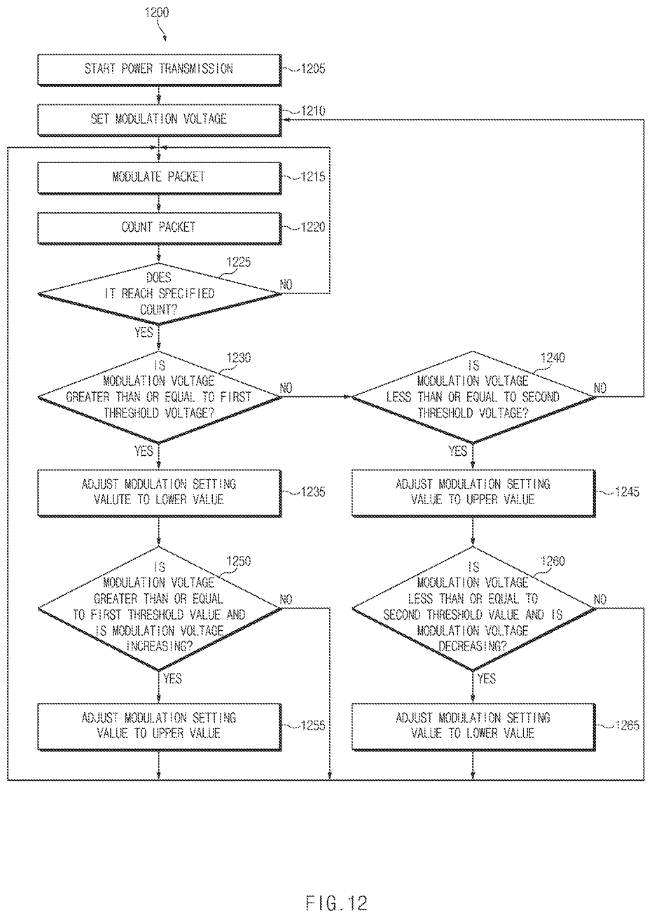

FIG. 12 is a flowchart 1200 illustrating a method for controlling a modulation depth according to an embodiment of the disclosure.

In operation 1205, a power transmission device 310, according to an embodiment, may start power transmission. In another embodiment, the power transmission device 310 may wirelessly transmit power using a transmit coil (e.g., a transmit coil 315 of FIG. 3).

In operation 1210, a processor (e.g., a processor 120 of FIG. 3) of a power reception device 320, according to an embodiment, may set a modulation voltage. In another embodiment, the processor 120 may set the modulation voltage to a value in a specified range.

In operation 1215, the processor 120, according to an embodiment, may modulate a packet. The processor 120 may start to modulate a packet when performing in-band communication associated with wireless power transmission. In another embodiment, the processor 120 may modulate a signal transmitted to a charging device 310 in in-band communication for each packet.

In operation 1220, the processor 120, according to an embodiment, may count the packet. The processor 120 may measure the number of packets of a signal, while modulating the signal for in-band communication. In another embodiment, the processor 120 may number a current packet to identify which packet the current packet is. The processor 120 may number a packet while increasing a number one by one when moving on to the next packet.

In operation 1225, the processor 120, according to an embodiment, may determine whether it reaches a specified count. The specified count may be a unit for adjusting a modulation voltage. For example, when adjusting the modulation voltage every 3 packets, the processor 120 may determine whether the count is 3. When it reaches the specified count (operation 1225—YES), the processor 120 may proceed to operation 1230. When there is a count less than the specified count (operation 1225—NO), the processor 120 may return to operation 1215.

In operation 1230, the processor 120, according to an embodiment, may determine that the modulation voltage is greater than or equal to a first threshold voltage. When the modulation voltage is greater than or equal to the first threshold voltage (operation 1230—YES), the processor 120 may proceed to operation 1235. When the modulation voltage is less than the first threshold voltage (operation 1230—NO), the processor 120 may proceed to operation 1240.

In operation 1235, the processor 120, according to an embodiment, may adjust the modulation setting value to a lower value. In another embodiment, processor 120 may decrease a value of a mode of selecting one of a plurality of capacitance values by one. In yet another embodiment, the processor 120 may decrease a capacitance value selected among the plurality of capacitance values.

In operation 1240, the processor 120, according to an embodiment, may determine that the modulation voltage is less than or equal to a second threshold voltage. When the modulation voltage is less than or equal to the second threshold voltage (operation 1240—YES), the processor 120 may proceed to operation 1245. When the modulation voltage is greater than the second threshold voltage (operation 1240—NO), the processor 120 may return to operation 1210.

In operation 1245, the processor 120, according to an embodiment, may adjust the modulation setting value to an upper value. In another embodiment, the processor 120 may increase a value of the mode of selecting one of the plurality of capacitance values by one. In yet another embodiment, the processor 120 may increase a capacitance value selected among the plurality of capacitance values.

In operation 1250, the processor 120, according to an embodiment, may identify whether the modulation voltage is greater than or equal to the first threshold voltage and whether the modulation voltage is increasing. When the modulation voltage is greater than or equal to the first threshold voltage and when the modulation is increasing (operation 1250—YES), the processor 120 may proceed to operation 1255. When the modulation voltage is less than the first threshold voltage or when the modulation voltage is decreasing (operation 1235—NO), the processor 120 may return to operation 1215. For example, whether the modulation voltage is increasing or decreasing may be based on the result of comparing a modulation voltage of a current specified number (e.g., 3) of packets (e.g., packet numbers N to N+2) with a modulation voltage of a previous specified number (e.g., 3) of packets (e.g., N−3 to N−1).

In operation 1255, the processor 120, according to an embodiment, may adjust the modulation setting value to an upper value. In another embodiment, the processor 120 may increase a value of the mode of selecting one of the plurality of capacitance values by one. In yet another embodiment, the processor 120 may increase a capacitance value selected among the plurality of capacitance values.

In operation 1260, the processor 120, according to an embodiment, may determine whether the modulation voltage is less than or equal to a second threshold value and whether the modulation voltage is decreasing. When the modulation voltage is less than or equal to the second threshold voltage and when the modulation is decreasing (operation 1260—YES), the processor 120 may proceed to operation 1265. When the modulation voltage is greater than the second threshold voltage or when the modulation voltage is increasing (operation 1260—NO), the processor 120 may return to operation 1215.

In operation 1265, the processor 120, according to an embodiment, may adjust the modulation setting value to a lower value. In another embodiment, the processor 120 may decrease a value of the mode of selecting one of a plurality of capacitance values by one. In yet another embodiment, the processor 120 may decrease a capacitance value selected among the plurality of capacitance values.

The processor 120, according to an embodiment, may maintain a modulation depth within a specified range through operation 1235, operation 1245, operation 1255, and operation 1265. In another embodiment, the processor 120 may perform at least one of operation 1235, operation 1245, operation 1255, and operation 1265 at least once to maintain the modulation depth within the specified range. In yet another embodiment, the processor 120 may repeatedly perform the same operation in response to failing to control the modulation voltage in a direction intended when performing at least one of operation 1235, operation 1245, operation 1255, and operation 1265 once. In an embodiment, the processor 120 may select and perform at least one of operation 1235, operation 1245, operation 1255, and operation 1265 such that the modulation voltage is controlled in the intended direction. In another embodiment, the processor 120 may maintain the modulation depth within the specified range while modulating a signal transmitted to a charging device 310 in in-band communication.

When the technology of modulating the signal of the in-band communication described in the disclosure is applied, the modulation depth of the rectified voltage may be limited to within a set range. For example, the modulation depth of the rectified voltage may be dynamically controlled to decrease the maximum modulation depth from existing 1.2 V to 0.8 V.

When the technology of modulating the signal of the in-band communication described in the disclosure is applied to an actual system, there may be an effect of limiting the maximum modulation depth. The lower the threshold of the specified range of the modulation depth is set to be, the more the effect of decreasing audible noise may increase.

A power reception device (e.g., a power reception device 320 of FIG. 6A) according to various embodiments may include a power reception unit (e.g., a power reception unit 610 of FIG. 6A), a communication circuit (e.g., a communication circuit 620 of FIG. 6A), a modulation depth monitoring circuit (e.g., a modulation depth monitoring circuit 630 of FIG. 6A), and a processor (e.g., a processor 120 of FIG. 6A) electrically connected with the power reception unit 610, the communication circuit 620, and the modulation depth monitoring circuit 630. The power reception unit 610 may include a receive circuit (e.g., a receive circuit 611 of FIG. 6A) that receives power from a wireless power transmitter (e.g., a power transmission device 310 of FIG. 3) and includes a coil (e.g., a receive coil 321 of FIG. 3) and a first capacitor (e.g., a capacitor 421 of FIG. 4) and a rectifier circuit (e.g., a rectifier circuit 612 of FIG. 6A) that rectifies the power received by the receive circuit 611 to convert the power into DC power. The communication circuit 620 may include a plurality of detuning switching units (e.g., a first detuning switching unit 621 and a second detuning switching unit 622 of FIG. 6A), each of which includes a second capacitor (e.g., modulation capacitors 531, 532, 533, and 534 of FIG. 5) and a switch (e.g., switches 535, 536, 537, and 538 of FIG. 5) and changes a voltage of the power received in the coil 321 and a modulation circuit (e.g., a modulation circuit 623 of FIG. 6A) that turns on or off the switch 535, 536, 537, or 538 based on a control signal received from the processor 120. The modulation depth monitoring circuit 630 may monitor a voltage of the rectified DC power to measure a modulation depth and provides the processor 120 with the modulation depth. The processor 120 may identify a detuning switching unit to perform data modulation among the plurality of detuning switching units based on the modulation depth, may control the modulation circuit 623 such that data is modulated by means of the identified detuning switching unit and may limit the modulation depth such that the modulation depth belongs to a specified range, and may control the modulation circuit 623 based on the data to be transmitted to the wireless power transmitter 310.

In an embodiment, the modulation depth monitoring circuit 630 may obtain a voltage of the rectified DC power when the modulation circuit 623 turns on the switch 535, 536, 537, or 538 as a first voltage for each of a plurality of packets received by the communication circuit 620, may obtain a voltage of the rectified DC power when the modulation circuit 623 turns off the switch 535, 536, 537, or 538 as a second voltage for each of the plurality of packets, and may calculate an average value of difference values between the first voltage and the second voltage of each of the plurality of packets as the modulation depth.

In another embodiment, the processor 120 may dynamically select the detuning switching unit to perform the data modulation and may control the modulation depth to belong to the specified range.

In yet another embodiment, the processor 120 may select the detuning switching unit to perform the data modulation and may select a capacitance value associated with the data modulation.

In an embodiment, the processor 120 may change a capacitance value of the second capacitor 531, 532, 533, or 534 to implement a capacitance value associated with the data modulation, when the second capacitors 531, 532, 533, and 534 are variable capacitors.

In another embodiment, a memory (e.g., a memory 130 of FIG. 3) that stores a plurality of capacitance values associated with the data modulation in the form of a modulation control table may be further included. The processor 120 may select any one mode of implementing the any one capacitance value among a plurality of modes according to use or not, the plurality of modes being included in the modulation control table.

In yet another embodiment, the modulation control table may be configured such that a capacitance value changed upon the data modulation increases as an upper value changes.

In an embodiment, the processor 120 may be configured, when packet modulation occurs as wireless charging is started, measure the modulation depth for respective packets to calculate an average value.

In another embodiment, the processor 120 may be configured to take an average value for the other samples except for an upper certain rate and a lower certain rate among all sample values taking an average to calculate the average value of the modulation depth.

In yet another embodiment, the processor 120 may be configured to, when a magnitude of a modulation voltage during any one packet is greater than or equal to a first threshold voltage (e.g., a first threshold voltage 1011 of FIG. 10A) for upward modulation, increase a modulation voltage of a next packet.

In an embodiment, the processor 120 may be configured to, when a magnitude of the modulation voltage is greater than or equal to the first threshold voltage 1011 and when the modulation voltage continues increasing, decrease a magnitude of a next modulation voltage to the first threshold voltage 1011 or less.

In another embodiment, the processor 120 may be configured to, when a magnitude of a modulation voltage during any one packet is less than or equal to the first threshold voltage 1011 for downward modulation, decrease a modulation voltage of a next packet to a second threshold voltage (e.g., a second threshold voltage 1012 of FIG. 10C) or less through a voltage of a modulation off voltage (e.g., a modulation off voltage 840 of FIG. 8) or less.

In yet another embodiment, the processor 120 may be configured to, when a magnitude of the modulation voltage is less than or equal to the second threshold voltage 1012, increase a magnitude of a next modulation voltage.

In an embodiment, the processor 120 may be configured to, when the modulation voltage is greater than or equal to a first threshold voltage 1011 and is less than or equal to a maximum modulation voltage (e.g., a maximum modulation voltage 851 of FIG. 8) or less, adjust a modulation setting value to a lower value.

In another embodiment, the processor 120 may be configured to, when the modulation voltage increases in a next packet, adjust the modulation setting value to an upper value.

In yet another embodiment, the processor 120 may be configured to, when a modulation voltage is less than or equal to a second threshold voltage 1012 and is greater than or equal to a minimum modulation voltage (e.g., a minimum modulation voltage 852 of FIG. 8) or more, adjust a modulation setting value to an upper value.

In an embodiment, the processor 120 may be configured to, when the modulation voltage decreases in a next packet, adjust the modulation setting value to a lower value.

A method for controlling charging of a power reception device 320 according to various embodiments may include receiving power from a wireless power transmitter 310, rectifying the received power to convert the received power into DC power, monitoring a voltage of the rectified DC power to measure a modulation depth, identifying a detuning switching unit to perform data modulation based on the modulation depth, controlling a modulation circuit 623 such that data is modulated by means of the identified detuning switching unit and limiting the modulation depth such that the modulation depth belongs to a specified range, and controlling the modulation circuit 623 based on the data to be transmitted to the wireless power transmitter.

In an embodiment, the measuring of the modulation depth may include obtaining a voltage of the rectified DC power when the modulation circuit 623 turns on the switch 535, 536, 537, or 538 as a first voltage for each of a plurality of packets received by a communication circuit 620, obtaining a voltage of the rectified DC power when the modulation circuit 623 turns off the switch 535, 536, 537, or 538 as a second voltage for each of the plurality of packets, and calculating an average value of difference values between the first voltage and the second voltage of each of the plurality of packets as the modulation depth.

In another embodiment, the limiting of the modulation depth may include dynamically selecting the detuning switching unit to perform the data modulation and controlling the modulation depth to belong to the specified range.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A power reception device, comprising:
a power reception circuitry;
a communication circuit;
a modulation depth monitoring circuit; and
at least one processor electrically connected with the power reception circuitry, the communication circuit, and the modulation depth monitoring circuit,
wherein the power reception circuitry includes:
a receive circuit configured to receive power from a wireless power transmitter and include a coil and a first capacitor, and
a rectifier circuit configured to rectify the power received by the receive circuit to convert the power into direct current (DC) power,
wherein the communication circuit includes:
a plurality of detuning switching circuitries, each of which includes a second capacitor and a switch and changes a voltage of the power received in the coil, and
a modulation circuit configured to turn on or off the switch based on a control signal received from the at least one processor,
wherein the modulation depth monitoring circuit monitors a voltage of the rectified DC power to measure a modulation depth and provides the at least one processor with the modulation depth, and
wherein the at least one processor is configured to:
identify a detuning switching circuitry to perform data modulation among the plurality of detuning switching circuitries based on the modulation depth,
control the modulation circuit such that data is modulated by means of the identified detuning switching circuitry and limits the modulation depth such that the modulation depth belongs to a specified range, and
control the modulation circuit based on the data to be transmitted to the wireless power transmitter.

2. The power reception device of claim 1, wherein the modulation depth monitoring circuit is configured to:
obtain a voltage of the rectified DC power when the modulation circuit turns on the switch as a first voltage for each of a plurality of packets received by the communication circuit,
obtain a voltage of the rectified DC power when the modulation circuit turns off the switch as a second voltage for each of the plurality of packets, and
calculate an average value of difference values between the first voltage and the second voltage of each of the plurality of packets as the modulation depth.

3. The power reception device of claim 1, wherein the at least one processor is further configured to:
dynamically select the detuning switching circuitry to perform the data modulation and controls the modulation depth to belong to the specified range.

4. The power reception device of claim 1, wherein the at least one processor is further configured to:
select the detuning switching circuitry to perform the data modulation and selects a capacitance value associated with the data modulation.

5. The power reception device of claim 1, wherein the at least one processor is further configured to:
change a capacitance value of the second capacitor to implement a capacitance value associated with the data modulation, when the second capacitors are variable capacitors.

6. The power reception device of claim 1, further comprising:
a memory storing a plurality of capacitance values associated with the data modulation in a form of a modulation control table,
wherein the at least one processor is further configured to:
select any one mode of implementing the any one capacitance value among a plurality of modes according to use or not, the plurality of modes being included in the modulation control table.

7. The power reception device of claim 6, wherein the modulation control table is configured such that a capacitance value changed upon the data modulation increases as an upper value changes.

8. The power reception device of claim 1, wherein the at least one processor is further configured to:
when packet modulation occurs as wireless charging is started, measure the modulation depth for respective packets to calculate an average value.

9. The power reception device of claim 8, wherein the at least one processor is further configured to:
take an average value for the other samples except for an upper certain rate and a lower certain rate among all sample values taking an average to calculate the average value of the modulation depth.

10. The power reception device of claim 1, wherein the at least one processor is further configured to:
when a magnitude of a modulation voltage during any one packet is greater than or equal to a first threshold voltage for upward modulation, increase a modulation voltage of a next packet.

11. The power reception device of claim 10, wherein the at least one processor is further configured to:
when a magnitude of the modulation voltage is greater than or equal to the first threshold voltage and when the modulation voltage continues increasing, decrease a magnitude of a next modulation voltage to the first threshold voltage or less.

12. The power reception device of claim 1, wherein the at least one processor is further configured to:
when a magnitude of a modulation voltage during any one packet is less than or equal to a first threshold voltage for downward modulation, decrease a modulation voltage of a next packet to a second threshold voltage or less through a voltage of a modulation off voltage or less.

13. The power reception device of claim 12, wherein the at least one processor is further configured to:
when a magnitude of the modulation voltage is less than or equal to the second threshold voltage, increase a magnitude of a next modulation voltage.

14. The power reception device of claim 12, wherein the at least one processor is further configured to:
when the modulation voltage is greater than or equal to the first threshold voltage and is less than or equal to a maximum modulation voltage, adjust a modulation setting value to a lower value.

15. The power reception device of claim 14, wherein the at least one processor is further configured to:
when the modulation voltage increases in a next packet, adjust the modulation setting value to an upper value.

16. The power reception device of claim 1, wherein the at least one processor is further configured to:
when a modulation voltage is less than or equal to a second threshold voltage and is greater than or equal to a minimum modulation voltage, adjust a modulation setting value to an upper value.

17. The power reception device of claim 1, wherein the at least one processor is further configured to:
when a modulation voltage decreases in a next packet, adjust a modulation setting value to a lower value.

18. A method for controlling charging of a power reception device, the method comprising:
receiving power from a wireless power transmitter;
rectifying the received power to convert the received power into direct current (DC) power;
monitoring a voltage of the rectified DC power to measure a modulation depth;
identifying a detuning switching circuitry to perform data modulation based on the modulation depth;
controlling a modulation circuit such that data is modulated by means of the identified detuning switching circuitry and limiting the modulation depth such that the modulation depth belongs to a specified range; and
controlling the modulation circuit based on the data to be transmitted to the wireless power transmitter.

19. The method of claim 18, wherein the measuring of the modulation depth includes:
obtaining a voltage of the rectified DC power when the modulation circuit turns on a switch as a first voltage for each of a plurality of packets received by a communication circuit;
obtaining a voltage of the rectified DC power when the modulation circuit turns off the switch as a second voltage for each of the plurality of packets; and
calculating an average value of difference values between the first voltage and the second voltage of each of the plurality of packets as the modulation depth.

20. The method of claim 18, wherein the limiting of the modulation depth includes:
dynamically selecting the detuning switching circuitry to perform the data modulation and controlling the modulation depth to belong to the specified range.
